(19) United States
(12) Patent Application Publication
(10) Pub. No.: US 2025/0016954 A1
(43) Pub. Date: Jan. 9, 2025

(54) COOLING DEVICE FOR COOLING ELECTRONIC COMPONENTS

(71) Applicant: Robert Bosch GmbH, Stuttgart (DE)

(72) Inventors: Christoph Jatzek, Hechingen-Schlatt (DE); Max Florian Beck, Vaihingen An Der Enz (DE); Michael Mayer, Hohenstein (DE); Stefan Maurer, Hechingen-Schlatt (DE); Wolfram Kienle, Magstadt (DE)

(21) Appl. No.: 18/702,048

(22) PCT Filed: Nov. 15, 2022
(86) PCT No.: PCT/EP2022/081886

§ 371 Date: Apr. 17, 2024

(30) Foreign Application Priority Data
Nov. 26, 2021 (DE) 10 2021 213 357.6

(51) Int. Cl. H05K 7/20

(52) U.S. Cl. CPC H05K 7/20254

(57) ABSTRACT

The invention relates to a cooling device (1) for cooling electronic components (2), comprising: a bottom plate (3);—a top plate (4) which is a deep-drawn component having a recess (40), the bottom plate (3) and top plate (4) being disposed in such a way that the recess (40) forms a cooling channel (5) between the bottom plate (3) and the top plate (4), the cooling channel (5) extending in a longitudinal direction (11) from an inlet opening (51) to an outlet opening (52), wherein a cooling fluid flow of a cooling fluid can flow through the cooling channel (5) in the longitudinal direction (10);—at least one turbulator (6) which is disposed within a turbulator portion (56) of the cooling channel (5); and—at least one blocking element (20) which is disposed, with respect to the longitudinal direction (11) of the cooling channel (5), next to the turbulator (6) in a bypass region (55) of the cooling channel (5) between the turbulator (6), the top plate (4) and the bottom plate (3), for at least partially blocking a bypass flow (15) next to the turbulator (6).

### BACKGROUND

The present invention relates to a cooling device for the cooling of electronic components as well as an electronic arrangement.

Cooling devices for cooling electronic components, e.g. power modules in inverters, are known. For example, such cooling devices comprise cooling channels through which a liquid medium can flow. In this context, it is also known to dispose turbulators in the cooling channels in order to improve heat dissipation.

### SUMMARY

In contrast, the cooling device according to the invention is characterized by a particularly high efficiency with regard to cooling of the electronic components being cooled. According to the present invention, this is achieved by means of a cooling device for cooling electronic components comprising a bottom plate, a top plate, and at least one turbulator. The top plate is designed as a deep-drawn component which comprises a recess. In particular, the top plate is pot-shaped. The bottom plate and the top plate are disposed together so that a cooling channel is formed between the bottom plate and the top plate by the recess. The cooling channel in this case extends along a longitudinal direction from an inlet opening to an outlet opening. Preferably, when viewed at a sheet plane of the bottom plate, the cooling channel comprises an elongated area, in particular with rectangular geometry, which extends along the longitudinal direction, particularly defined by a straight line. An inlet opening and/or outlet opening can in this case be formed by open sides of the recess and/or by openings in the bottom plate and/or top plate. A cooling fluid flow of a cooling fluid can thereby flow through the cooling channel in the longitudinal direction from the inlet opening to the outlet opening. The at least one turbulator is disposed within a turbulator portion of the cooling channel. In particular, the turbulator is disposed between the top plate and the bottom plate. The cooling device also comprises at least one blocking element disposed, with respect to the longitudinal direction of the cooling channel, next to the turbulator. The at least one blocking element is in this case disposed in a bypass region of the cooling channel between the turbulator, the top plate, and the bottom plate. The blocking element causes at least partial blocking of a bypass flow next to the turbulator, in particular at the edge of the cooling channel.

Preferably, the turbulator extends completely through the cooling channel between the bottom plate and a region of the recess in the top plate parallel to the bottom plate, in particular such that the turbulator adjoins the bottom plate and the region of the recess in the top plate parallel to it.

The bottom plate and the top plate can, e.g., adjoin one another in sections. Alternatively, an intermediate layer can be disposed between the bottom plate and the top plate.

In particular, the bottom plate and the top plate are connected to each other by means of a hard solder joint.

In other words, the blocking element is located in the bypass region next to the turbulator, which is in particular designed as a solid body and takes in at least part of the bypass region. As a result, the cross section of the bypass region available for flow is significantly reduced or completely filled. As a result, a bypass flow in the bypass region next to the turbulator, i.e. at the edge of the cooling channel, can be significantly reduced. For example, a manufacturing-related demolding geometry of the top plate, which comprises radii and/or slopes, is situated in this bypass region. For example, the turbulator cannot thereby fill the entire flow cross-section of the cooling channel, whereby a partial region of the cooling fluid flow, i.e. the bypass flow, is able to flow past the turbulator. This bypass flow is reduced or completely blocked by the at least one blocking element, so a significantly reduced or no volume flow of the cooling fluid can flow past the turbulator. The at least one blocking element in this case offers a particularly simple and cost-effective means of manufacture for reducing the bypass flow. Given that a greater proportion of the cooling fluid flow must therefore flow through the turbulator, increased turbulence can be provided in the cooling fluid flow, which leads to a particularly efficient cooling effect of the cooling device.

The blocking element preferably features a cross-sectional geometry which is adapted to a demolding geometry of the top plate. A manufacturing-related geometry of the cover sheet as a deep-drawn component is considered to be a demolding geometry. In other words, the deformation geometry in particular is characterized by demolding slopes and/or radii of the top plate at the recess, which are necessary in particular due to the deep drawing of the top plate. The cross-sectional geometry of the blocking element is in particular designed to have a shape similar to a right-angled triangle, in particular, whereby the “base” of the right-angled triangle is not a straight line, but is adapted to the shape of the cover sheet in the region of the edge of the recess. As a result, a particularly large portion of the bypass region can be blocked by the blocking element, which can particularly effectively reduce the bypass flow.

The blocking element is preferably designed to be cuboid. As a result, the blocking element can be manufactured in a particularly simple and cost-effective manner. Preferably, the top plate comprises pockets in which the blocking element can be inserted, whereby the pockets form local extensions of the recess.

Preferably, the blocking element is formed at least in part, more preferably entirely, by a hard solder meniscus of a hard solder joint of the bottom plate and the top plate. In particular, the hard solder joint is designed for the fluid-tight and mechanical connection of the bottom plate and the top plate, in particular at one edge of the recess. The hard solder meniscus is a partial region of the hard solder joint that faces the cooling channel and, in particular, protrudes into it. In particular, the hard solder meniscus is made of the soldering material. For example, the hard solder meniscus comprises a concave cross-section and merges tangentially into the top plate or bottom plate. In particular, when the blocking element is formed by the hard solder meniscus, the hard solder connection is in this case designed such that the hard solder meniscus fills a portion of the bypass region, in particular as large a portion as possible. As a result, the reduced bypass flow can be achieved in a particularly simple manner and without any additional components.

Preferably, the blocking element is formed at least partially by an inclined partial region of the turbulator. In particular, the inclined partial region is a laser-machined partial region. In other words, a turbulator is provided that has a width that is greater than a minimum width of the recess. The edges of the turbulator are in this case inclined, in particular by means of laser machining, i.e., a part is removed so that the inclined partial region of the turbulator extends into the bypass region. As a result, a reduction in the bypass flow can be achieved in a simple manner and without any additional components.

Preferably, the blocking element comprises at least one undercut region extending away from the turbulator and which partially undercuts the top plate with respect to the longitudinal direction. In particular, the undercut region can be considered as a protruding nose of the blocking element, which protrudes laterally towards the edge of the cooling channel. In particular, the undercut region protrudes into a pocket of the top plate, which in particular forms a widening of the cooling channel, thus forming the undercut with respect to the longitudinal direction. The undercut region causes an additional deflection of partial regions of the cooling fluid flow close to the edge. As a result, the bypass flow can be further decelerated and reduced.

Preferably, the cooling device comprises a plurality of turbulators disposed in the cooling channel in succession along the longitudinal direction. For example, the turbulators can be designed be identical or, alternatively, to differ from one another.

Further preferably, the cooling device comprises a plurality of blocking elements for each turbulator. As a result, multiple obstacles are able to be provided for the bypass flow in order to reduce it particularly effectively.

Particularly preferably, at least one blocking element is disposed on both sides of the turbulator, in particular symmetrically with respect to the longitudinal direction.

Preferably, each blocking element extends in the flow direction across a plurality of turbulators. As a result, a particularly simple design can be provided while using few components.

Preferably, the plurality of turbulators feature increasing turbulence factors along the longitudinal direction. The term “turbulence factor” is in particular considered to be a degree of turbulence in the cooling fluid flow caused by the turbulator. For example, a turbulator can comprise a plurality of turbulence plates, each of which is inclined at a predetermined turbulence angle to the flow direction. For example, a first turbulence angle of a first turbulator in the flow direction can be 10°, whereby in particular a second turbulence angle of a second turbulator can be 15°, and, e.g., a third turbulence angle of a third turbulator can be 20°. A particularly high cooling effect of the cooling device can be achieved as a result.

Further preferably, at least one taper of a flow cross-section of the cooling channel is designed upstream and/or downstream of the turbulator section, in particular for redirecting a partial region of the cooling fluid close to the wall within the cooling channel. In other words, the cooling channel upstream and/or downstream of the turbulator section is narrowed by the taper, particularly locally, so that flow lines of cooling fluid at the edge of the cooling channel are redirected by this taper and cannot continue straight through the cooling channel. This deflection causes the taper to decelerate the cooling fluid flow close to the edge. In particular, a pressure drop in the partial region of the cooling fluid flow close to the edge is created as a result. As a result, a bypass flow next to the turbulator, i.e. at the edge of the cooling channel, is able to be reduced. Preferably, the taper is formed by a bead of the top plate, which is in particular substantially orthogonal to the longitudinal direction and protrudes from one edge of the cooling channel into the cooling channel. For example, the bead can already be produced by the deep-drawing process of the top plate.

Preferably, the taper is designed such that a minimum width of the flow cross-section in the taper is less than a width of the turbulator. In this context, the term “width” is considered to be a dimension in a direction perpendicular to the flow direction or the longitudinal direction and in a direction parallel to a sheet plane of the bottom plate. In particular, the minimum width of the flow cross-section in the taper is at most 90%, preferably at most 80%, of the maximum width of the turbulator. As a result, a significant deflection of the partial region of the cooling fluid flow close to the edge is reliably ensured in order to achieve a particularly effective reduction of the bypass flow.

The invention further relates to an electronic arrangement comprising the described cooling device and at least one electronic component that is being cooled. The electronic component being cooled is preferably a power module of a power electronics unit. The electronic arrangement is in particular a power electronic component, e.g. an inverter. The highly efficient cooling device can also enable a particularly high efficiency and longevity for the electronic component.

Preferably, the electronic component being cooled is connected to the bottom plate of the cooling device in a thermally conductive manner, e.g. by means of a copper layer. In particular, the electronic component is disposed on the bottom plate in the region of the turbulator, i.e., opposite to the turbulator on the bottom plate. Preferably, multiple electronic components that are being cooled can be disposed on the bottom plate for each turbulator.

### BRIEF DESCRIPTION OF THE DRAWINGS

The invention is described in the following with reference to exemplary embodiments in conjunction with the drawings. In the drawings, functionally identical components are identified with respectively identical reference characters. Shown are:

FIG. 1 a view of a cooling device according to a first exemplary embodiment of the invention,

FIG. 2 a sectional view of an electronic arrangement with the cooling device in FIG. 1,

FIG. 3 a view of a cooling device according to a second exemplary embodiment of the invention,

FIG. 4 a view of a cooling device according to a fourth exemplary embodiment of the invention,

FIG. 5 a detail of the cooling device in FIG. 1, and

FIG. 6 a detail of a cooling device according to a fifth exemplary embodiment of the invention.

### DETAILED DESCRIPTION

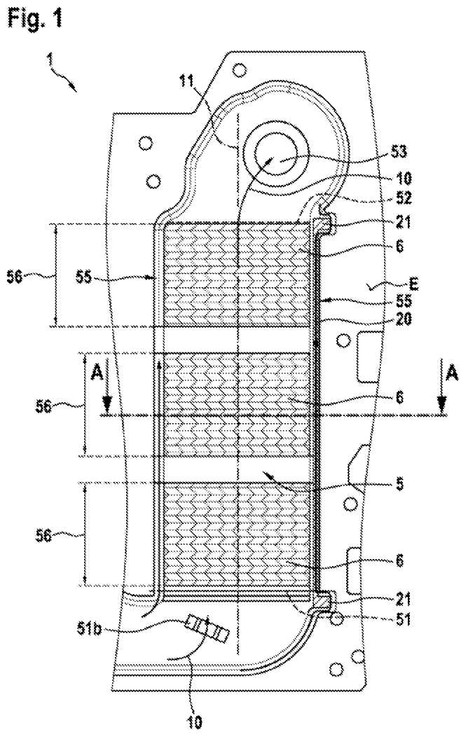

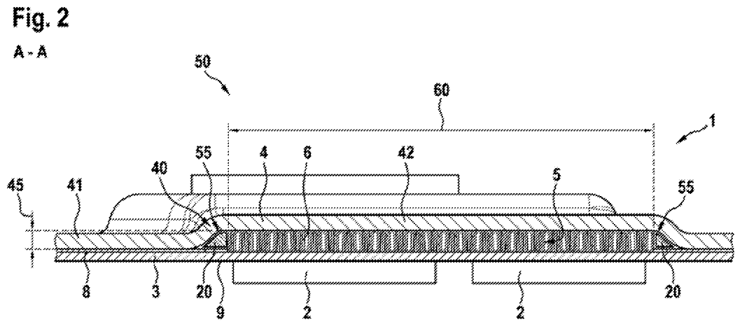

FIG. 1 shows a cooling device 1 according to a first exemplary embodiment of the invention. In FIG. 2, a sectional view of an electronic arrangement 50 comprising the cooling device 1 in FIG. 1 is shown along the section line A-A.

The cooling device 1 comprises a bottom plate 3 and a top plate 4. In FIG. 1, the cooling device 1 is shown without the bottom plate 3 for the sake of clarity.

The bottom plate 3 and top plate 4 are each made of a metal, preferably aluminum.

The bottom plate 3 is designed as a straight flat plate.

The top plate 4 is designed as a deep-drawn component which comprises a recess 40. The recess 40 is in particular formed by the fact that the top surfaces of flat sheet portions 41, 42 of the top plate 4 are disposed parallel to each other and at a predefined distance 45 to each other (see FIG. 2).

The bottom plate 3 and top plate 4 are disposed together so that a cooling channel 5 is formed between the bottom plate 3 and top plate 4 by the recess 40. In particular, the bottom plate 3 and the first sheet portion 41 of the top plate 4 are in this case connected to each other by means of a hard solder connection.

An intermediate plate 8 can be disposed between the bottom plate 3 and top plate 4, as shown in FIG. 2. For example, the intermediate plate 8 can provide an additional distance to a top side of the top plate 4 in order to adjust a height of the cooling channel 5. Alternatively, the bottom plate 3 and first sheet portion 41 of the top plate 4 can also adjoin one another directly.

The recess 40, and thus the cooling channel 5, can be elongated with respect to a plane E of the top plate 4, in particular at least in sections having a rectangular shape (see FIG. 1).

The cooling channel 5 extends at least in sections, in particular symmetrically, along a longitudinal direction 11, which is in particular designed as a straight line.

The cooling channel 5 also extends at least from an inlet opening 51 to an outlet opening 52 and a cooling fluid flow can flow through it along the longitudinal direction 10 from the inlet opening 51 to the outlet opening 52.

The inlet opening 51 and the outlet opening 52 are each defined as cross-sections of the cooling channel 5 in a cross-sectional plane perpendicular to plane E at the beginning and end of the rectangular region.

In particular, the cooling passage 5 can comprise an inlet region 51a leading to the inlet opening 51 and an outlet region 52a connecting to the outlet opening 52. In the outlet region 52a, an exit opening 53 penetrating the top plate 4 is provided, through which the cooling fluid flow can exit the cooling device 1.

The inlet region 51a can be disposed angled to the rectangular region of the cooling channel 5, as shown in FIG. 1. For example, a deflection element 51b can be provided in the inlet region 51a to deflect a direction of the cooling fluid flow towards the inlet opening 51.

The cooling device 1 further comprises a total of three turbulators 6, which are disposed within the cooling channel 5. Each turbulator 6 is in this case disposed in a turbulator portion 56 extending along the longitudinal direction 11.

Each turbulator 6 can, e.g., feature a rectangular cross-section as seen from above (as in FIG. 1), whereby its width 60 transverse to the flow direction 10 is, e.g., greater than its length along the flow direction 10.

The cooling device 1 is provided for cooling electronic components 2, e.g. for power electronic devices, such as inverters. FIG. 2 shows a corresponding electronic arrangement 50 comprising the cooling device 1 and a plurality of electronic components 2.

The electronic components 2 are connected to the bottom plate 3 in a thermally conductive manner. To improve the conduction of heat, a copper coating 9 can, e.g., be provided between the bottom plate 3 and electronic components 2.

The electronic components 2 are disposed within or in the region of the turbulator portions 56 when viewed along the plane E of the top plate 4 (see FIG. 1).

Each turbulator 6 comprises a plurality of turbulence plates disposed at an angle to the longitudinal direction 11 in order to turbulently swirl the cooling fluid flowing through the cooling channel 5. As a result, heat from the electronic components 2 can be dissipated particularly effectively by means of the cooling fluid.

Preferably, each turbulator 6 comprises a respective plurality of turbulence plates disposed at a predetermined angle to the longitudinal direction 11. Particularly preferably, the turbulators 6 each comprise turbulence plates at a greater angle to the longitudinal direction 11 along the flow direction 10. In other words, the turbulators 6 each feature higher turbulence factors in the flow direction 10. As a result, the best possible heat dissipation from the electronic components 2 by means of the cooling fluid can still be achieved, even using the turbulators 6 located further downstream, where the heat transfer from the electronic components 2 results in a higher cooling fluid temperature than using the turbulators 6 located further upstream.

To achieve a high cooling efficiency, as much of the flow cross-section of the cooling channel 5 as possible is covered by the turbulator 6. Given that the top plate 4 is a deep-drawn component, a demolding slope and radii on the edge of the recess 40 are required for the demolding process during deep drawing. Given that the turbulators 6 comprise rectangular cross-sections, there are bypass regions 55 on the edge of the flow channel laterally next to the turbulators 6 and between the turbulators 6, the top plate 4 and the bottom plate 3, where no turbulent swirling of the cooling fluid flow exists (see FIG. 2).

In order to minimize a bypass flow 15 through the bypass regions 55 to the extent possible (and thereby provide as high a cooling effect as possible for the cooling device 1), the cooling device 1 further comprises at least one blocking element 20. The blocking element 20 is disposed next to the turbulator 6 in the bypass region 55.

The blocking element 20 is in this case provided as an additional component, which can be inserted into the bypass region 55 during the assembly of the cooling device 1.

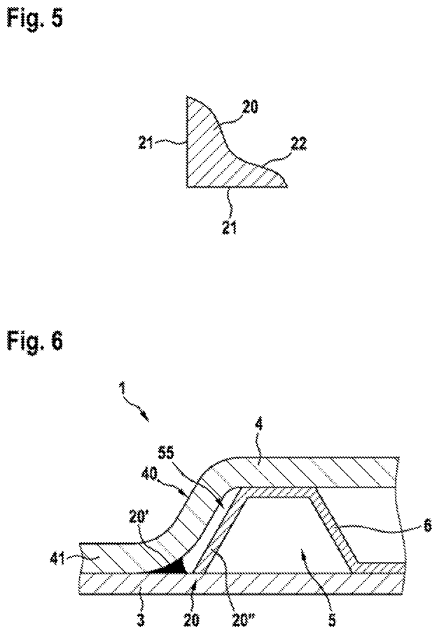

The blocking element 20 features a predefined cross-sectional geometry, which is adapted to a demolding geometry of the deep-drawn top plate 4. This can in particular be seen in FIG. 2. Furthermore, FIG. 5 shows an enlarged cross-sectional view of the blocking element 20 of FIGS. 1 and 2. As can be seen in FIG. 5, the blocking element 20 features a cross-sectional geometry similar to a right-angled triangle having two straight sides 21 arranged at right angles to each other and a “base” 22. The base 22 in this case features a shape adapted to the demolding geometry of the top plate 4 such that the blocking element 20 can fill in as much of the bypass region 55 as possible.

The blocking element 20 in this case extends in the longitudinal direction 11 over all of the turbulators 6.

The bypass region 55 is substantially completely blocked by the blocking element 20, as can be seen in FIG. 2 in particular. As a result, the cooling fluid flow must substantially pass entirely through the turbulators 6 when flowing through the cooling channel 5. As a result, a particularly effective utilization of the cooling potential of the cooling fluid flow is enabled in order to be able to optimally cool the electronic components 2.

The blocking element 20 further comprises, as shown in FIG. 1, two undercut regions 21 which extend outwardly away from the turbulator 6. The undercut regions 21 project in this case into corresponding pockets of the top plate 4. The undercut regions 21 partially undercut the top plate 4 when viewed parallel to the longitudinal direction 11. The result is forcing additional deflections of partial portions of the cooling fluid flow close to the edge, thereby further reducing the bypass flow 15.

Only a single blocking element 20 is shown in FIG. 1. Preferably, a blocking element 20 is provided on both sides of the turbulators 6 for a particularly efficient reduction of the bypass flow 15.

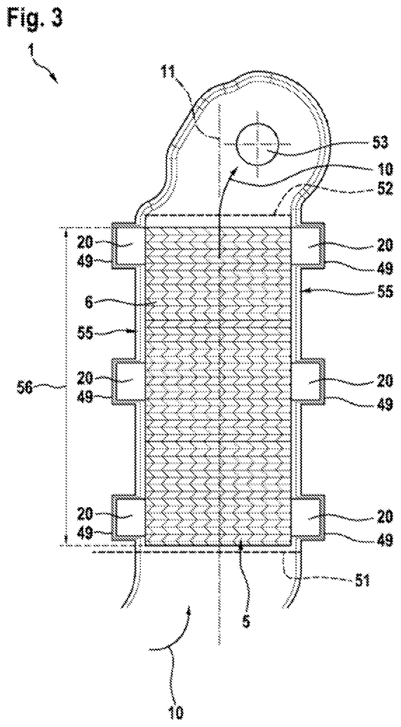

FIG. 3 shows a view of a cooling device 1 according to a second exemplary embodiment of the invention. Said second exemplary embodiment substantially corresponds to the first exemplary embodiment in FIG. 1, with the difference being an alternative embodiment of the blocking elements 20. In addition, the cooling device 1 of the second exemplary embodiment (instead of a plurality of turbulators 6) only comprises a single turbulator 6, which extends substantially over the entire cooling channel 5. In particular, the single turbulator 6 can feature different turbulence factors along the flow direction 10, e.g. due to different setting angles of the turbulence plates, in order to achieve the same effect as the plurality of turbulators 6 in the first exemplary embodiment in FIG. 1.

In the second exemplary embodiment in FIG. 3, the blocking elements 20 are each designed as cuboids, in particular made of aluminum. The blocking elements 20 are in this case disposed directly next to the turbulator 6 in a direction transverse to the longitudinal direction 11. In addition, each blocking element 20 is disposed in a pocket 49 of the top plate 4, whereby the pockets 49 are in particular part of the recess 40.

In the third exemplary embodiment, a total of three blocking elements 20 are disposed on each side of the turbulator 6, whereby two opposing blocking elements 20 are disposed at the same height with respect to the longitudinal direction 11.

The blocking elements 20 in this case form local blockages of the bypass regions 55 in the cooling device 1 of the second embodiment, as a result of which the bypass flow 15 can also be effectively reduced.

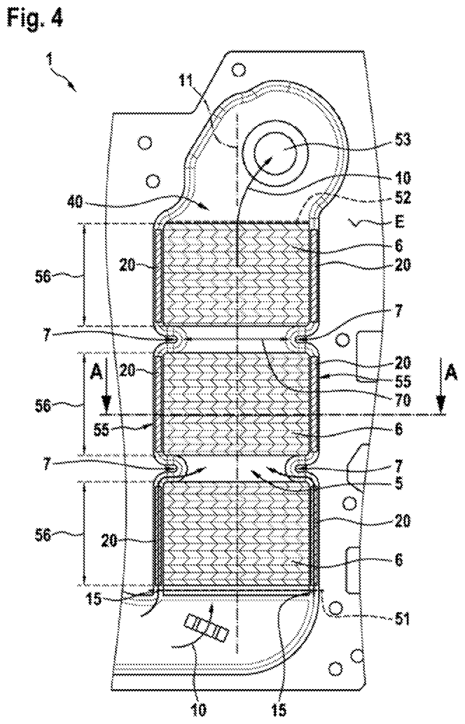

FIG. 4 shows a view of a cooling device 1 according to a third exemplary embodiment of the invention. The third exemplary embodiment substantially corresponds to the first exemplary embodiment in FIG. 1, with the difference that two blocking elements 20 are provided separately for each turbulator 6. Furthermore, the cooling device 1 of the third exemplary embodiment additionally comprises tapers 7 of the flow cross-section of the cooling channel 5 in each case between the turbulator portions 56. The tapers 7 cause deflections of partial portions of the cooling fluid flow close to the edge, as indicated by arrows B in FIG. 4. These deflections cause a deceleration, and thus a pressure drop in the partial portions of the cooling fluid flow close to the edge, thereby also reducing the volume flow passing through the bypass regions 55.

The tapers 7 are in the form of beads of the top plate 4, which are disposed on the edge of the recess 40. In other words, the tapers 7 are in the form of projections extending laterally into the cooling channel 5, which extend in particular over the entire height of the cooling channel 5 in a direction perpendicular to the plane E.

A minimum width 70 of the flow cross-section in the tapers 7 is less, preferably 10% less, than a width 60 of the turbulator 6. As a result, turbulators 6 and tapers 7 undercut each other when viewed along the flow direction 10, forcing a particularly reliable flow deflection at the edge of the cooling channel 5.

The tapers 7 are designed symmetrically with respect to the longitudinal direction 11, as can be seen in FIG. 1. In other words, two tapers 7 are in each case formed opposite one another at the edges of the cooling channel 5.

The two opposing tapers 7 narrow the flow cross-section of the cooling channel 5 in this region, such that the flow cross-section is at least 5% smaller than the total flow cross-section of the cooling channel 56 within one of the turbulator portions 56. In this context, the expression “total cross-section between the top plate 4 and the bottom plate 3” is considered to be the total flow cross-section.

FIG. 6 shows a detail sectional view of a cooling device 1 according to a fifth exemplary embodiment of the invention. The fifth exemplary embodiment substantially corresponds to the first exemplary embodiment in FIG. 1, with the difference that no separate component is provided as the blocking element 20. Instead, the blocking element 20, which causes the bypass flow 15 to be at least partially blocked, is formed by a hard solder meniscus 20′ of the hard solder connection between the bottom plate 3 and the top plate 4. The hard solder meniscus 20′ is in this case the soldering material located on a side facing the cooling channel 5 between the top plate 4 and bottom plate 3 and at a region where the bottom plate 3 and top plate 4 touch. The bypass region 55 can be easily reduced by using a correspondingly enlarged hard solder meniscus 20′ in order to achieve a lower bypass flow 15.

In addition, in the fifth exemplary embodiment shown in FIG. 6, the blocking element 20 is partially formed by an inclined partial region 20″ of the turbulator 6. This inclined partial region 20″ can be manufactured by laser processing. As a result, the turbulator 6 is able to feature a corresponding shape adapted to the demolding geometry of the top plate 4, so it can be arranged closer to the edge of the cooling channel 7. As a result, the bypass region 5 can also be reduced.

1. A cooling device for cooling electronic components (2), comprising:
a bottom plate (3),
a top plate (4) which is a deep-drawn component having a recess (40),
wherein the bottom plate (3) and the top plate (4) are disposed in such a way the recess (40) forms a cooling channel (5) between the bottom plate (3) and the top plate (4),
wherein the cooling channel (5) extends in a longitudinal direction (11) from an inlet opening (51) to an outlet opening (52),
wherein a cooling fluid flow of a cooling fluid can flow through the cooling channel (5) in the longitudinal direction (11),
at least one turbulator (6) which is disposed within a turbulator portion (56) of the cooling channel (5), and
at least one blocking element (20) which is disposed, with respect to the longitudinal direction (11) of the cooling channel (5), next to the turbulator (6) in a bypass region (55) of the cooling channel (5) between the turbulator (6), the top plate (4), and the bottom plate (3) for at least partially blocking a bypass flow (15) next to the turbulator (6).

2. The cooling device according to claim 1, wherein the blocking element (20) has a cross-sectional geometry configured to a demolding geometry of the top plate (4).

3. The cooling device according to claim 1, wherein the blocking element (20) is configured to be cuboid.

4. The cooling device according to claim 1, wherein the blocking element (20) is at least partially formed by a hard solder meniscus (20′) of a hard solder joint of the bottom plate (3) and top plate (4).

5. The cooling device according to claim 1, wherein the blocking element (20) is at least partially formed by an inclined partial portion (20″) of the turbulator (6).

6. The cooling device according to claim 1, wherein the blocking element (20) comprises at least one undercut region (21), which extends away from the turbulator (6) and which partially undercuts the top plate (4) with respect to the longitudinal direction (11).

7. The cooling device according to claim 1, comprising a plurality of turbulators (6) disposed in succession in the cooling channel (5) in a flow direction (10).

8. The cooling device according to claim 1, comprising a plurality of blocking elements (20) for each turbulator (6).

9. The cooling device according to claim 7, wherein each blocking element (20) extends in a flow direction (10) across the plurality of turbulators (6).

10. The cooling device according to claim 7, wherein the turbulators (6) include increasing turbulence factors in the flow direction (10).

11. The cooling device according to claim 1, wherein at least one taper (7) of a flow cross-section of the cooling channel (5) is formed upstream and/or downstream of the turbulator portion (56).

12. The cooling device according to claim 11, wherein the taper (7) is configured such that a minimum width (70) of the flow cross-section in the taper (7) is less than a width (60) of the turbulator (6).

13. An electronic arrangement comprising:
a cooling device (1) according to claim 1, and
at least one electronic component (2) that is to be cooled.

14. The electronic arrangement according to claim 13, wherein the electronic component (2) being cooled is connected to the bottom plate (3) of the cooling device (1) in a thermally conductive manner.

15. The cooling device according to claim 5, wherein the blocking element (20) is at least partially formed by laser machining.

16. The cooling device according to claim 4, wherein the blocking element (20) is at least partially formed by an inclined partial portion (20″) of the turbulator (6).

17. The cooling device according to claim 16, wherein the blocking element (20) is at least partially formed by laser machining.

18. The cooling device according to claim 8, wherein the turbulators (6) include increasing turbulence factors in the flow direction (10).

19. The cooling device according to claim 9, wherein the turbulators (6) include increasing turbulence factors in the flow direction (10).
